(19) United States
(12) Patent Application Publication
(10) Pub. No.: US 2026/0060119 A1
(43) Pub. Date: Feb. 26, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Taira TABAKOYA, Chiba Chiba (JP)

(21) Appl. No.: 19/029,574

(22) Filed: Jan. 17, 2025

(30) Foreign Application Priority Data
Aug. 23, 2024 (JP) 2024-141760

(51) Int. Cl. H01L 23/498; H01L 23/00; H01L 23/29; H01L 23/31; H01L 25/07; H10D 80/20

(52) U.S. Cl. CPC H01L 23/49844; H01L 23/29; H01L 23/3142; H01L 24/32; H01L 25/072; H10D 80/251; H01L 24/48; H01L 24/73; H01L 2224/32245; H01L 2224/48091; H01L 2224/48245; H01L 2224/48472; H01L 2224/73265; H01L 2924/13091

(57) ABSTRACT

A semiconductor device includes: a first terminal and a second terminal; a first conductive member that is electrically connected to the first terminal; a semiconductor chip that is provided on the first conductive member; a second conductive member that is provided on the semiconductor chip and electrically connected to the second terminal; a first insulator that is provided on the second conductive member and covers the semiconductor chip; a conductive plate that is provided on at least a part of the first insulator; and a post that is electrically connected to the conductive plate and extends along a side surface of the first insulator.

### CROSS-REFERENCE TO RELATED APPLICATION(S)

This application is based upon and claims the benefit of priority from Japanese Patent Application No. 2024-141760, filed Aug. 23, 2024, the entire contents of which are incorporated herein by reference.

### FIELD

Embodiments described herein relate generally to a semiconductor device.

### BACKGROUND

In some semiconductor packages, a metal plate is provided on the upper and lower surfaces of the package in order to improve heat dissipation. In addition, magnetic shielding plates may be provided between a plurality of chips, in order to reduce mutual inductance between a plurality of paths of current flowing into the semiconductor package.

### BRIEF DESCRIPTION OF THE DRAWINGS

FIG. 1 is a perspective view of a semiconductor device according to a first embodiment.

FIG. 2 is a top view of the semiconductor device according to the first embodiment.

FIG. 3 is a top view of the semiconductor device according to the first embodiment.

FIG. 4 is a cross-sectional view taken along the line A1-A2 shown in FIGS. 1-3, of the semiconductor device according to the first embodiment.

FIG. 5A is a cross-sectional view taken along the line B1-B2 shown in FIGS. 1-3, of the semiconductor device according to the first embodiment.

FIG. 5B is a cross-sectional view taken along the line B1-B2 shown in FIGS. 1-3, of another example of the semiconductor device according to the first embodiment.

FIG. 6A is a cross-sectional view taken along the line C1-C2 shown in FIGS. 1-3, of the semiconductor device according to the first embodiment.

FIG. 6B is a cross-sectional view taken along the line C1-C2 shown in FIGS. 1-3, of another example of the semiconductor device according to the first embodiment, which is taken along line C1-C2 shown in FIG. 1.

FIG. 7 is a cross-sectional view of a semiconductor device according to a first modification of the first embodiment.

FIG. 8 is a perspective view of a semiconductor device according to a second modification of the first embodiment.

FIG. 9 is a perspective view of a semiconductor device according to a third modification of the first embodiment.

FIG. 10 is a perspective view of a semiconductor device according to a second embodiment.

FIG. 11 is a cross-sectional view taken along the line D1-D2 shown in FIG. 10, of the semiconductor device according to the second embodiment.

FIG. 12 is a cross-sectional view of the semiconductor device according to the second embodiment.

FIG. 13 is a perspective view of a semiconductor device according to a third embodiment.

FIG. 14 is a circuit diagram of the semiconductor device according to the third embodiment.

FIG. 15 is a top view of the semiconductor device according to the third embodiment.

### DETAILED DESCRIPTION

Embodiments provide a semiconductor device having improved switching performance.

In general, according to one embodiment, a semiconductor device includes: a first terminal and a second terminal; a first conductive member that is electrically connected to the first terminal; a semiconductor chip that is provided on the first conductive member; a second conductive member that is provided on the semiconductor chip and electrically connected to the second terminal; a first insulator that is provided on the second conductive member and covers the semiconductor chip; a conductive plate that is provided on at least a part of the first insulator; and a post that is electrically connected to the conductive plate and extends along a side surface of the first insulator.

According to another embodiment, a semiconductor device includes: a first conductive member; a semiconductor chip that is provided on the first conductive member; a second conductive member that is provided on the semiconductor chip; a first insulator that is provided on the second conductive member and covers the semiconductor chip; and a conductive plate that is provided on the first insulator and has at least a part facing the second region in a first direction; and a conductive base that can be used as a terminal for external connections; and a conductive layer that electrically connects the conductive plate and the conductive base.

According to another embodiment, a semiconductor device includes: a first terminal and a second terminal; a first conductive member that is electrically connected to the first terminal; a semiconductor chip that is provided on the first conductive member; a second conductive member that is provided on the semiconductor chip and electrically connected to the second terminal; a first insulator that is provided on the second conductive member and covers the semiconductor chip; and a conductive plate that is provided on at least a part of the first insulator, wherein the first insulator is directly interfaced with the second conductive member and the conductive plate.

Hereinafter, embodiments of the present disclosure will be described with reference to the drawings.

It should be noted that the drawings are schematic or conceptual, and the relationship between the thickness and width of each part, the size ratio between parts, and the like are not necessarily the same as those in a real situation. Further, even when the same part is shown, the dimensions or ratios of the part may differ from each other depending on the drawings.

It should be noted that, in the specification and the drawings of the present application, the same reference numerals and signs are given to the same elements as those described above in the given drawings. Thus, detailed descriptions will be omitted as appropriate.

A direction from a first conductive member 20 to a semiconductor chip 40 is set as a Z direction (which may be referred to herein as the first direction). Further, a direction orthogonal to the Z direction is set as an X direction (which may be referred to herein as the second direction), and a direction intersecting the X direction and the Z direction is set as a Y direction (which may be referred to herein as the third direction). A semiconductor device 100 illustrated in FIG. 2 is shown as a cross-sectional view in an XZ plane. The X, Y, and Z directions are shown as orthogonal in the present embodiment, but the directions are not limited to orthogonal, but may intersect with each other in a non-orthogonal manner. Further, for the purpose of description, the positive direction of the Z direction is referred to as “upper”, and the negative direction of the Z direction is referred to as “lower”. However, the “upper” and “lower” directions are not limited to the directions of gravity or the directions when the semiconductor device is mounted.

### First Embodiment

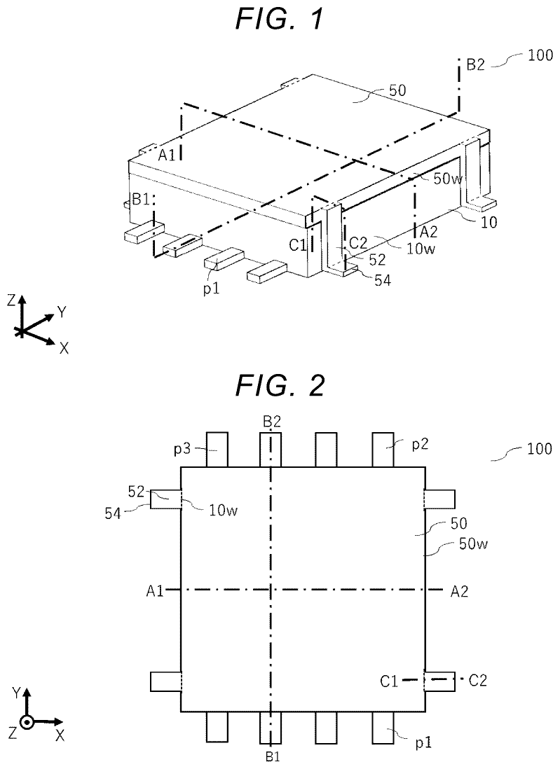

FIG. 1 is a perspective view illustrating a semiconductor device 100 according to a first embodiment. The semiconductor device 100 has a first insulator 10, a first terminal p1 that protrudes from the first insulator 10, a conductive plate 50 that is provided on the first insulator 10, and a post 52 that is connected to the conductive plate 50. The semiconductor device 100 is, for example, a surface-mount device (SMD) package.

The first insulator 10 encapsulates a semiconductor chip 40 not shown in FIG. 1. The first insulator 10 is made of, for example, resin. The first insulator 10 has a side surface 10w which is a surface intersecting with the X direction or the Y direction. FIG. 1 shows an example in which the first insulator 10 has a total of four side surfaces 10w in the positive and negative directions of the X direction and the positive and negative directions of the Y direction.

The first terminal p1 protrudes from the first insulator 10 in the side surface 10w, enabling electrical connection between an external circuit and the semiconductor device 100. The first terminal p1 protrudes from the first insulator 10 in the negative direction of the Y direction in the side surface 10w. The first terminal p1 is one of the external terminals of the semiconductor device 100. It should be noted that the semiconductor device 100 may further have an external terminal which is not shown in FIG. 1.

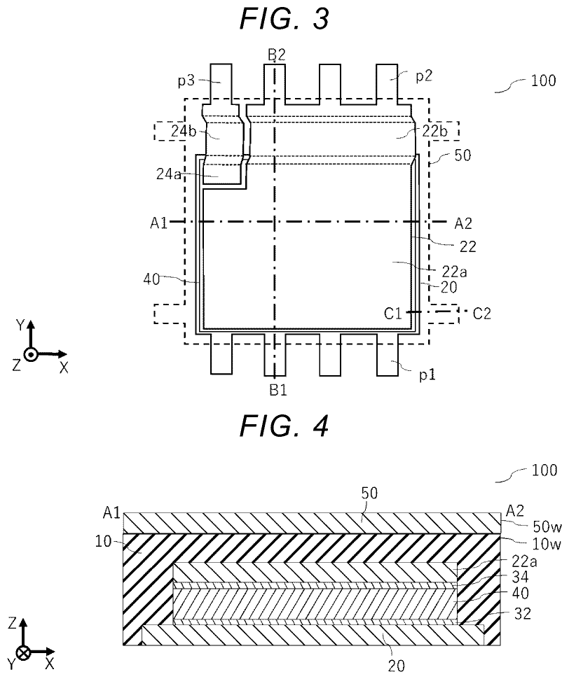

The conductive plate 50 is provided on the first insulator 10. The conductive plate 50 may be provided on at least a part of the first insulator 10. The conductive plate 50 desirably includes a material having high electrical conductivity and thermal conductivity. A desired example of a position at which the conductive plate 50 is provided will be described later with reference to FIG. 3.

The post 52 is continuous with the conductive plate 50. For example, the post 52 is formed integrally with the conductive plate 50. The conductive plate 50 may be connected to the post 52 at least electrically or thermally. The post 52 has a part that extends in the Z direction. The post 52 extends in the Z direction along the side surface 10w of the first insulator 10. The post 52 may be separated from the first insulator 10 in the X direction, or may be in contact with at least a part of the first insulator 10. Preferably, the post 52 traverses the side surface 10w of the first insulator 10 in the Z direction. Here, A traversing B in the Z direction means that A extends from the end of B in the positive direction of the Z direction to the end of B in the negative direction of the Z direction.

A base 54 may be further provided continuously with the post 52, on the side of the post 52 opposite to the conductive plate 50. The base 54 extends, for example, along a plane (here, the XY plane) intersecting with the Z direction. The base 54 can be used as a terminal for connecting, for example, the conductive plate 50 and the post 52 to the external circuit.

The first terminal p1 (and a second terminal p2 or a third terminal p3 illustrated in FIG. 2 and thereafter) is provided on the side surface 10w positioned on the positive or negative side in the Y direction. Meanwhile, the post 52 and the base 54 are provided on the side surface 10w positioned on the positive or negative side in the X direction. In order to prevent the first terminal p1 and the base 54 from interfering with each other (for example, coming into contact with each other) and to prevent a short circuit, it is desirable that the post 52 is provided on the side surface 10w different from the side surface 10w on which the first terminal p1 is provided or the second terminal p2 and the third terminal p3 are provided as will be described later with reference to FIG. 2. Further, for example, the post 52 and the base 54 are spaced apart from the side surface 10w, on which the first terminal p1 is provided, in the positive direction of the Y direction. In other words, the post 52 is connected to the conductive plate 50 at a position where the post 52 is misaligned in the Y direction from a corner portion in the XY plane of the conductive plate 50. The first terminal p1 is spaced apart from the post 52 and the base 54 in the Y direction. Therefore, the first terminal p1 can be more reliably electrically insulated from the post 52 and the base 54.

FIG. 1 shows an example in which four posts 52 and four bases 54 are provided, but the number of posts 52 and the number of bases 54 are not limited to this. Regarding positions in which the posts 52 are provided, FIG. 1 shows an example in which the posts 52 are provided near corners of the semiconductor device 100, but the positions are not limited to this. In order to further ensure insulation with the first terminal p1 and the like, the post 52 may be further separated from the first terminal p1. Further, at least some of the plurality of posts 52 and the plurality of bases 54 provided may be replaced with wires, for example.

FIG. 2 is a top view of the semiconductor device 100 according to the present embodiment.

The first terminal p1 also shown in FIG. 1 is provided on the negative side in the Y direction. Meanwhile, a second terminal p2 is provided on the positive side in the Y direction. Further, the third terminal p3 is further provided on the same side as the side where the second terminal p2 is provided. The semiconductor device 100 includes, for example, metal-oxide-semiconductor field-effect transistors (MOSFETs) inside the package. The first terminal p1 is, for example, a drain terminal, the second terminal p2 is, for example, a source terminal, and the third terminal p3 is, for example, a gate terminal.

In FIG. 2, the first insulator 10 is not illustrated since the first insulator 10 is positioned under the conductive plate 50. The conductive plate 50 and the first insulator 10 may overlap with each other at least partially in the Z direction. For example, a side surface 50w of the conductive plate 50 and the side surface 10w of the first insulator 10 may overlap with each other partially in the Z direction. The side surface 50w is exposed from the first insulator 10. In FIG. 2, the side surface 10w of the first insulator 10 is provided between the post 52 and the conductive plate 50, for example, at a position indicated by a dashed line. That is, the post 52 protrudes from the side surface 10w of the first insulator 10 toward the positive or negative side in the X direction.

FIG. 3 is a top view of the semiconductor device 100 according to the present embodiment. Here, the first insulator 10, the conductive plate 50, the post 52, and the base 54 are illustrated in a transparent manner (the conductive plate 50, the post 52, and the base 54 are shown as regions surrounded by dashed lines). That is, FIG. 3 illustrates the semiconductor chip 40 and the conductive member which are covered by the first insulator 10 in FIGS. 1 and 2.

The first conductive member 20 is continuous with the first terminal p1. The first conductive member 20 is, for example, a metal member such as a die pad. The semiconductor chip 40 is provided on the first conductive member 20, and a second conductive member 22 is further provided on the semiconductor chip 40.

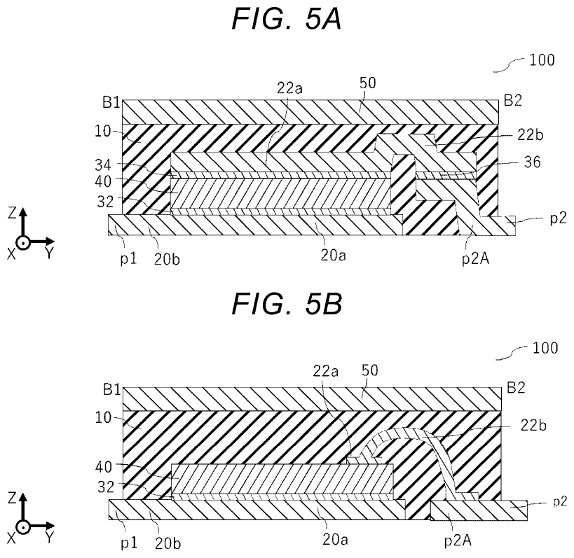

The second conductive member 22 is connected to the second terminal p2 and has a first region 22a and a second region 22b. The first region 22a is a region overlapping with the semiconductor chip 40 in the Z direction. The second region 22b is provided between the first region 22a and the second terminal p2. It should be noted that a structure as illustrated in FIGS. 5A and 5B described below may be provided between the second region 22b and the second terminal p2, and a region between the second region 22b and the second terminal p2 may not always be integrally formed.

The semiconductor chip 40 includes a transistor such as a MOSFET, for example, and a gate pad of the semiconductor chip 40 is connected to, for example, the third terminal p3. A third conductive member 24 is provided on the semiconductor chip 40. The third conductive member 24 has a first region 24a and a second region 24b. The first region 24a overlaps with the semiconductor chip 40 in the Z direction. The second region 24b is provided between the first region 24a and the third terminal p3.

The first terminal p1 and the first conductive member 20 have, for example, a potential equivalent to a drain potential. The second terminal p2 and the second conductive member 22 have, for example, a potential equivalent to a source potential. The third terminal p3 and the third conductive member 24 have, for example, a potential equivalent to a gate potential.

Further, in the description in FIG. 3 and thereafter, the so-called drain-down structure is described. In the structure, the second terminal p2 and the third terminal p3 (for example, the source terminal and the gate terminal) are connected to the electrodes on the upper surface of the semiconductor chip 40. However, the present disclosure may be applied to the source-down structure.

FIG. 4 is a cross-sectional view taken along the XZ plane passing through the line A1-A2 illustrated in FIGS. 1 to 3.

The semiconductor chip 40 is provided on the first conductive member 20 with a bonding member 32 interposed therebetween. The first region 22a of the second conductive member 22 is provided on the semiconductor chip 40 with a bonding member 34 interposed therebetween.

The semiconductor chip 40 has electrodes on the upper surface and the lower surface, respectively. The semiconductor chip 40 includes, for example, a MOSFET. The semiconductor chip 40 has a source electrode and a gate pad separated from the source electrode on the upper surface, and a drain electrode on the lower surface. For example, the first conductive member 20 is electrically connected to the drain electrode of the semiconductor chip 40. For example, the second conductive member 22 is electrically connected to the source electrode of the semiconductor chip 40.

The first insulator 10 covers the semiconductor chip 40. In other words, the first insulator 10 encapsulates the semiconductor chip 40. The first insulator 10 is provided on the second conductive member 22, and the conductive plate 50 is provided on the first insulator 10.

The conductive plate 50 has, for example, a longer length in the X direction than the second conductive member 22. Further, the conductive plate 50 may have a longer length in the X direction than the first conductive member 20.

FIG. 4 shows an example in which the side surface 10w of the first insulator 10 and the side surface 50w of the conductive plate 50 overlap at least partially with each other in the Z direction. However, the conductive plate 50 may be smaller than the first insulator 10 in the XY plane, and may partially protrude out of the first insulator 10.

FIGS. 5A and 5B are a cross-sectional views taken along the XZ plane passing through the line B1-B2 illustrated in FIGS. 1 and 2.

First, FIG. 5A will be described. FIG. 5A is a cross-sectional view taken along the XZ plane passing through the line B1-B2 for the example illustrated in FIG. 4.

The semiconductor chip 40 is provided on the first conductive member 20. The bonding member 32 is interposed between the first conductive member 20 and the semiconductor chip 40. The first region 22a of the second conductive member 22 faces the semiconductor chip 40 in the Z direction. The bonding member 34 is interposed between the semiconductor chip 40 and the first region 22a. The second region 22b of the second conductive member 22 is positioned between the first region 22a and the second terminal p2. The second conductive member 22 connects the second terminal p2 to the semiconductor chip 40. Further, an end region p2A is provided between the second region 22b and the second terminal p2, which is continuous with the second terminal p2, and is in contact with the first insulator 10. The second terminal p2 and the end region p2A are, for example, leads (which are, e.g., plate-shaped metal members), and may include the same material as the first terminal p1 and the first conductive member 20.

The first insulator 10 covers the semiconductor chip 40 and is provided at least on the second conductive member 22. The first insulator 10 is provided on the first region 22a and the second region 22b of the second conductive member 22.

The first region 22a and the second region 22b are, for example, integrally formed. A bonding member 36 is interposed between the second region 22b and the end region p2A, for example, as illustrated in FIG. 5A. However, the second region 22b and the end region p2A may be integrally formed.

The conductive plate 50 has, for example, a longer length in the Y direction than the second conductive member 22. The conductive plate 50 overlaps with the first region 22a and the second region 22b of the second conductive member 22 in the Z direction. Further, the conductive plate 50 has a longer length in the X direction than the second conductive member 22.

Next, FIG. 5B, which has a different configuration from the examples illustrated in FIG. 4 and FIG. 5A, will be described. The direction of the cross-section shown in FIG. 5B is the same as the direction in FIG. 5A. FIG. 5B has a configuration of the second conductive member 22 different from configurations of FIGS. 4 and 5A. The second conductive member 22 has the first region 22a connected to the semiconductor chip 40, and the second region 22b positioned between the first region 22a and the second terminal p2. The second region 22b is, for example, a wire formed through bonding. The wire includes a circular wire and a flat wire, also known as a ribbon. The first region 22a is electrically connected to, for example, a source electrode on the upper surface of the semiconductor chip 40. The wire is made of, for example, a conductive material of which a cross-section orthogonal to the extending direction has a circular shape. The ribbon is made of, for example, a conductive material of which a cross-section orthogonal to the extending direction has an elliptical or oval shape.

The end region p2A is continuous with the second terminal p2. For example, the second region 22b, which is a wire, has one end connected to the semiconductor chip 40 through bonding, and the other end connected to the end region p2A through bonding.

As illustrated in FIGS. 5A and 5B, the configuration for connecting the second terminal p2 to the semiconductor chip 40 may employ a pre-formed plate-shaped metal member, and may also include a bonded wire or ribbon. Here, the plate shape refers to a shape in which, for example, the length dimension in the Z direction (also referred to herein as thickness) is smaller than the length dimensions in the X direction and the Y direction. The plate-shaped metal member is subjected to pre-bending processing, and the like, as necessary, and is provided on the semiconductor chip 40 through the bonding member 34. From the viewpoint of heat dissipation, it may be desirable to use a plate-shaped metal member that is able to flow current over a wider region. On the other hand, in a similar manner to a wire or a ribbon, the shape of the second conductive member 22 may be determined by bonding from the semiconductor chip 40 to the second terminal p2.

Subsequently, referring to FIGS. 5A and 5B, the positional relationship between the conductive plate 50 and the second conductive member 22 will be described. FIG. 5A shows an example in which the conductive plate 50 is provided on the front surface over the first insulator 10. However, the conductive plate 50 may be provided on at least a part of the first insulator 10.

The conductive plate 50 is provided at a position at which at least a portion overlaps with the second region 22b in the Z direction. In other words, at least a part of the conductive plate 50 faces the second region 22b in the Z direction with the first insulator 10 interposed therebetween. Further, it is desirable that at least a part of the conductive plate 50 faces the first region 22a in the Z direction with the first insulator 10 interposed therebetween. It is desirable that an area in which the conductive plate 50 and the second conductive member 22 face each other with the first insulator 10 interposed therebetween is large.

In both cases of FIGS. 5A and 5B, a desired positional relationship between the conductive plate 50 and the second conductive member 22 is the same. In both cases of FIGS. 5A and 5B, the electric signal transmitted between the semiconductor chip 40 and the second terminal p2 passes through the second region 22b of the second conductive member 22. It is desirable that the conductive plate 50 overlaps with the current path passing through the second region 22b in the Z direction in order to improve the switching performance, as described later.

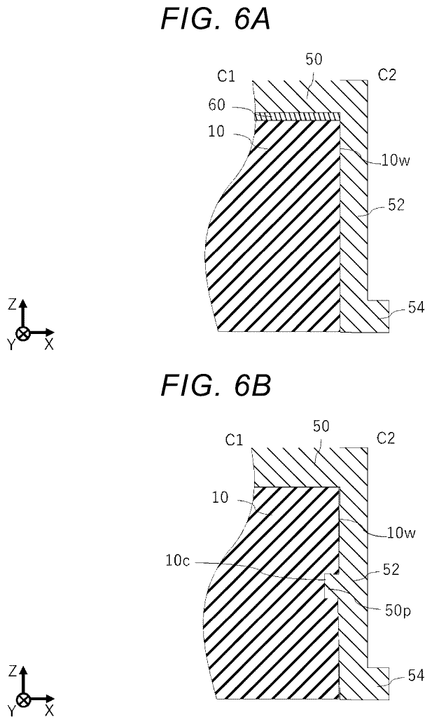

FIGS. 6A and 6B are cross-sectional views taken along the XZ plane passing through the line C1-C2 illustrated in FIGS. 1 to 3. FIGS. 6A and 6B show a structure between the first insulator 10 and the conductive plate 50 and the post 52.

FIG. 6A shows an example in which an adhesive portion 60 is provided between the first insulator 10 and the conductive plate 50. The adhesive portion 60 is in contact with the first insulator 10 and the conductive plate 50 and fixes the positions of the conductive plate 50 and the post 52 relative to the first insulator 10. That is, the conductive plate 50 and the post 52 are prevented from being misaligned from the first insulator 10. It is desirable that the adhesive portion 60 is provided in at least a part of the space between the first insulator 10 and the conductive plate 50.

As illustrated in FIG. 6A, the first insulator 10 may be in direct contact with the post 52. Although not shown in FIG. 6A, a gap may be provided between the first insulator 10 and the post 52. In FIG. 6B, a gap may also be provided between the first insulator 10 and the post 52.

FIG. 6B shows an example of another structure capable of preventing the conductive plate 50 and the post 52 from being misaligned from the first insulator 10. The post 52 has a protrusion 50p that protrudes in the negative direction of the X direction from the surface on the side of the first insulator 10 in the post 52. A recess 10c is provided at a position corresponding to the protrusion 50p on the side surface 10w of the first insulator 10. That is, a protrusion 10p of the post 52 fits into the recess 10c of the first insulator 10.

FIG. 6B shows an example in which the first insulator 10 has the recess 10c and the post 52 has the protrusion 10p. However, the first insulator 10 may have the protrusion and the post 52 may have the recess. Further, the configuration in which the recess is provided in the post 52 may include a configuration in which a hole penetrating the post 52 in the X direction is provided.

In both structures illustrated in FIGS. 6A and 6B, the conductive plate 50 and the post 52 are prevented from being misaligned from the first insulator 10.

Examples of materials for the elements will be described below.

The first insulator 10 is, for example, a sealing resin containing an epoxy resin.

The first conductive member 20 is made of, for example, a metal such as an alloy containing Cu. The second conductive member 22 is made of, for example, a metal such as an alloy containing Cu.

The conductive plate 50 is made of, for example, a metal such as an alloy containing Cu.

The semiconductor chip includes a semiconductor substrate containing at least one element selected from, for example, Si, SiC, C, GaAs, and Ge.

The bonding members 32, 34, and 36 include, for example, solder.

The adhesive portion 60 includes, for example, a silicone-based adhesive. The silicone-based adhesive is an adhesive containing silicone.

Referring again to FIG. 5A, the operation of the semiconductor device 100 will be described.

An example, in which an electric signal is transmitted from the first terminal p1 to the second terminal p2, will be described. However, the direction in which the electric signal is transmitted is not limited to this. Further, an example, in which the semiconductor chip 40 includes a MOSFET, will be described. However, the type of the semiconductor chip 40 is not limited to a MOSFET.

An electric signal is input to an electrode provided on the lower surface of the semiconductor chip 40 through the first terminal p1 and the first conductive member 20. For example, a drain electrode of the MOSFET is provided on the lower surface of the semiconductor chip 40. Meanwhile, the potential of the gate electrode of the MOSFET of the semiconductor chip 40 is controlled by controlling the potential applied to the third terminal p3 illustrated in FIG. 3.

If a potential of the gate electrode of the MOSFET of the semiconductor chip 40 is greater than a threshold voltage, the semiconductor chip 40 outputs an electric signal from the source electrode provided on the upper surface. Referring again to FIG. 5A, the output electric signal is transmitted to the first region 22a of the second conductive member 22, and is output to the external circuit from the second terminal p2 through the second region 22b.

An example of the flow of current when the electric signal is current will be described with reference to FIG. 5A. First, the current flows in the positive direction of the Y direction from the first terminal p1 to the first conductive member 20. Further, the current flows in the positive direction of the Z direction from the first conductive member 20 to the first region 22a of the second conductive member through the semiconductor chip 40. The current flows in the positive direction of the Y direction from the first region 22a to the second region 22b (the second conductive member 22 is bent, and thus may include a part in which the current flows along the Z direction). The current flows from the second region 22b to the second terminal p2.

For example, a current path from the first terminal p1 to the second terminal p2 is formed as described above. The cross-section illustrated in FIG. 5A continues while having the same cross-sectional structure in the X direction. Thus, it can be thought that the current path flowing from the first terminal p1 to the second terminal p2 is also present in the X direction in addition to the YZ plane illustrated in FIG. 5A. Here, the current path is not necessarily a path through which current actually flows, but also includes a virtual current path through which current is likely to flow. In addition, in the semiconductor device 100, there are multiple current paths such as wiring inside the semiconductor chip 40 and a path of current passing through the third terminal p3 illustrated in FIG. 3.

It is known that a plurality of current paths cause mutually induced electromotive force via the magnetic field generated by the current. When the induced electromotive force is generated to cause a temporal change in the current at the time of switching or the like, the current is likely to start to flow in the virtual current path.

In the current path from the first terminal p1 to the second terminal p2, mutually induced electromotive force is generated between the plurality of current paths lined up in the YZ plane and the X direction. Two of the plurality of current paths positioned between the first terminal p1 and the second terminal p2 are referred to as a first path I1 and a second path I2 (not shown in the drawing) for convenience. Then, the mutually induced electromotive force is generated between the first path I1 and the second path I2. That is, for example, when the semiconductor device 100 is turned off, the current flowing through the first path I1 may decrease. In such a case, the magnetic field generated by the current flowing through the first path I1 decreases. Then, the second path I2 induces an electromotive force in the direction in which the current increases so as to reduce the temporal change of the magnetic field. The more rapidly the current flowing through the first path I1 decreases, the greater the induced electromotive force generated in the second path I2 becomes. The same relationship is established even when the first path I1 and the second path I2 are swapped. Further, when the semiconductor device 100 is turned on, a mutually induced electromotive force may also be generated.

That is, when the semiconductor device is turned off (or turned on), the induced electromotive force is generated in the direction in which the current decreases or increases in response to a corresponding turn-on or turn-off operation, and the voltage waveform at the time of switching may oscillate. In general, the greater the induced electromotive force (=mutual inductance) generated between the plurality of current paths, the more likely it is that the induced electromotive force will be generated at the time of switching the semiconductor device. Thus, there is a concern that the switching performance may deteriorate due to oscillation of the voltage waveform.

In the semiconductor device 100 according to the present embodiment, the voltage waveform is prevented from oscillating due to the induced electromotive force at the time of switching. Thereby, it is possible to provide a semiconductor device having improved switching performance. The semiconductor device 100 has a conductive plate 50, and current flows in the conductive plate 50 in a direction in which the temporal change of the magnetic field at the time of switching is reduced. With such a configuration, by reducing the induced electromotive force generated between the plurality of current paths between the first terminal p1 and the second terminal p2 (reducing the mutual inductance), it is possible to reduce oscillation at the time of switching. By reducing the oscillation of the voltage waveform, it is possible to perform a stable switching operation. As a result, even when the switching frequency is increased, it is possible to satisfactorily maintain switching characteristics.

Referring to FIG. 5A, a description will be given of reducing the effect of the change in the magnetic field at the time of switching by using the conductive plate 50. A description will be given of a part of the current path between the first terminal p1 and the second terminal p2, in which current flows through the first region 22a and the second region 22b. For example, a situation where the current flows from the first region 22a to the second region 22b is considered.

The current flowing from the first region 22a to the second region 22b generates a magnetic field in a vortex shape around the current. As the current changes with time at the time of switching, the magnetic field generated around the current changes with time, and an induced electromotive force is generated in the surrounding current path. In the present embodiment, assuming a virtual closed circuit in the conductive plate 50, an induced electromotive force is also generated in the closed circuit due to the temporal change of the magnetic field that penetrates the closed circuit in the Z direction. That is, an eddy current is generated in the closed circuit of the conductive plate 50 in the direction in which the temporal change of the magnetic field is reduced. In addition, the current flowing into the conductive plate 50 also generates a magnetic field. The magnetic field generated by the current flowing into the conductive plate 50 is generated in the direction in which the temporal change of the magnetic field is reduced. Therefore, since the temporal change of the magnetic field is reduced, the induced electromotive force between the paths of current flowing from the first region 22a to the second region 22b can be reduced. By providing the conductive plate 50, oscillation at the time of switching can be reduced.

For example, the induced electromotive force between the paths of current flowing along the XY plane is mainly generated by the temporal change of the magnetic field in the direction along the Z direction. The reason for this is that the magnetic field that penetrates the closed circuit in the XY plane has a directional component along the Z direction. When an eddy current is generated in the conductive plate 50, the eddy current generates the magnetic field in the direction along the Z direction. Depending on the direction of rotation of vortex of the eddy current, the magnetic field is in the positive direction of the Z direction or the negative direction of the Z direction. That is, it is possible to generate a magnetic field in a direction, in which the temporal change of the magnetic field in the Z direction is reduced, by the eddy current generated in the XY plane in the conductive plate 50. In order to reduce the induced electromotive force between the paths of current flowing along the XY plane, it is effective to provide the conductive plate 50 along the XY plane, like the semiconductor device 100 according to the present embodiment.

It should be noted that the current generated in the conductive plate 50 is not limited to the eddy current. For example, the conductive plate 50 is connected to an external circuit through the post 52 and the base 54 illustrated in FIG. 1. Therefore, a current may flow between the conductive plate 50 and the external circuit.

The conductive plate 50 overlaps at least partially with the first region 22a or the second region 22b in the Z direction. Thus, it is possible to reduce the temporal change of the magnetic field generated by the current flowing through the first region 22a or the second region 22b.

For example, when the semiconductor device 100 is mounted on a substrate or the like, the first conductive member 20 comes into at least partial contact with the substrate. The magnetic field generated by the current flowing through the first conductive member 20 may have a temporal change that is reduced by wiring provided inside the substrate.

On the other hand, the current flowing through the second conductive member 22 flows along a current path that is separated from the substrate in the positive direction of the Z direction. Therefore, the effect of reducing the temporal change of the magnetic field by the substrate may be smaller than that of the first conductive member 20. In the semiconductor device 100 according to the present embodiment, it is possible to reduce the temporal change of the magnetic field for the current flowing through the second conductive member 22 by using the conductive plate 50 provided on the first insulator 10 and electrically insulated from the second conductive member 22.

In the semiconductor device 100 according to the present embodiment, the conductive plate 50, the post 52, and the base 54 serve as paths for heat flow. Therefore, local overheating can be suppressed and the reliability of the semiconductor device can be improved. For example, a case will be described in which the semiconductor device 100 is mounted on the substrate or the like, and the base 54 comes into contact with the substrate or the like.

The current density of the current flowing in the Z direction from the first conductive member 20 to the second conductive member 22 in the semiconductor chip 40 may be different between the center portion and the terminal base of the semiconductor chip 40 in the XY plane. For example, the current density at the center portion of the semiconductor chip 40 may be greater than the current density at the terminal base of the semiconductor chip 40. Thus, an amount of heat generated at the center portion may be greater than an amount of heat generated at the terminal base.

The amount of heat generated is different between the part in which the semiconductor chip 40 is provided and the other part in the XY plane. The amount of heat generated is greater in the part where the semiconductor chip 40 is provided than in the part where the semiconductor chip 40 is not provided. That is, heat generation regions with large and small amount of heat may be generated in the semiconductor device 100, in accordance with the disposition of the semiconductor chip 40 and the bias of the current density inside the semiconductor chip 40.

In the semiconductor device 100 according to the present embodiment, the conductive plate 50 contains, for example, a material having a higher thermal conductivity than the first insulator 10, and thus heat tends to diffuse in the conductive plate 50. Accordingly, even when the thermal distribution inside the semiconductor device 100 is uneven in the XY plane, the heat conducted to the conductive plate 50 is rapidly diffused in the conductive plate 50. Thereby, the amount of heat generated in the XY plane can be made more uniform. In addition, the heat is widely diffused in the conductive plate 50. Therefore, for example, an area, in which the high-temperature part comes into contact with the environment including the surrounding atmosphere, increases. As a result, it is easy to dissipate heat. The semiconductor device 100 can be prevented from locally overheating and the reliability of the semiconductor device can be improved.

The conductive plate 50 can be thermally connected to the external circuit through the post 52 and the base 54. Since the external circuit functions as a heat sink, the heat diffused in the conductive plate 50 is further conducted to the outside of the semiconductor device 100. By preventing heat from accumulating in the conductive plate 50, the conductive plate 50 can further absorb heat from the first insulator 10.

In the semiconductor device 100 according to the present embodiment, the conductive plate 50 can be electrically connected to the external circuit through the post 52 and the base 54. For example, in FIG. 1, the external circuits can be connected to traverse the semiconductor device 100 from the negative side to the positive side in the X direction or to traverse the semiconductor device 100 in the opposite direction. That is, a circuit positioned on the positive side in the X direction, a circuit positioned on the negative side in the X direction, the base 54, the post 52, the conductive plate 50, the post 52, and the base 54 can be connected to the semiconductor device 100 in this order. The layout of the wiring for the circuit around the semiconductor device 100 can be made shorter.

For comparison, it is assumed that the semiconductor device does not have the post 52 and the base 54. In such a case, it is necessary to provide wiring so as to bypass the semiconductor device 100, for example, rather than traversing the semiconductor device 100 from the negative side to the positive side in the X direction or traversing the semiconductor device 100 in the opposite direction. Consequently, an area is necessary to provide wiring for bypassing the substrate on which the semiconductor device is mounted.

In the semiconductor device 100 according to the present embodiment, it is possible to further integrate the semiconductor device by shortening the layout of the wiring.

### First Modification of First Embodiment

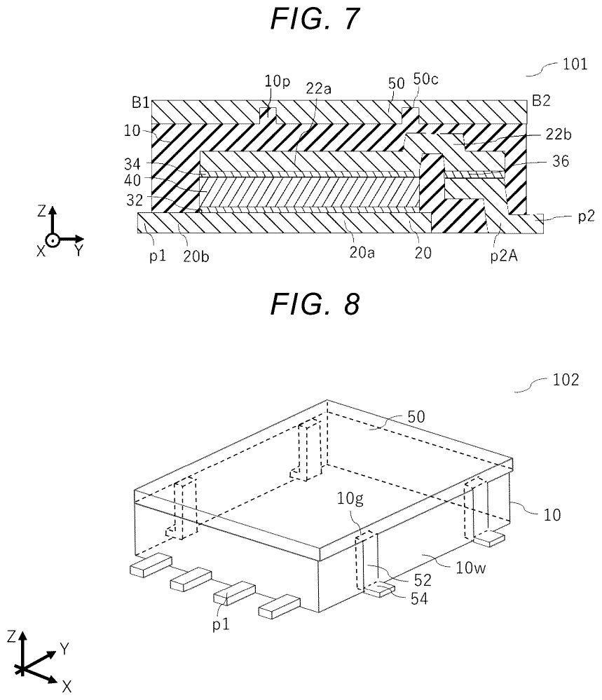

FIG. 7 is a cross-sectional view illustrating a semiconductor device 101 according to a first modification of the first embodiment. It should be noted that FIG. 7 shows a cross-section at the same position as the cross-section along the line B1-B2 illustrated in FIGS. 1 to 3. The description of the common parts in the semiconductor device 100 according to the first embodiment will not be repeated.

In the semiconductor device 101 according to the present modification, the conductive plate 50 provided on the first insulator 10 has a recess 50c. Further, the first insulator 10 has the protrusion 10p at a position at which the first insulator 10 overlaps with the recess 50c in the Z direction. The protrusion 10p fits into the recess 50c. It should be noted that the recess 50c may be a hole penetrating the conductive plate 50 in the Z direction. The protrusion 10p can have either a rectangular or circular shape in the XY plane. For example, the protrusions 10p are aligned in a dotted layout within the XY plane. Alternatively, the protrusions 10p can extend in the Y direction and be aligned in a striped layout within the XY plane.

In the semiconductor device 101 according to the present modification, the alignment of the conductive plate 50 with the first insulator 10 can be easily and reliably performed. When the conductive plate 50 is provided on the first insulator 10 such that the protrusion 10p fits into the recess 50c, the misalignment therebetween can be reduced to be less than the difference in the dimensions of the protrusion 10p and the recess 50c. For example, when the protrusion 10p and the recess 50c are designed to fit together perfectly, at least theoretically, the conductive plate 50 can be prevented from being misaligned from the first insulator 10.

In the semiconductor device 101 according to the present modification, a configuration, which reduces the misalignment between the conductive plate 50 and the first insulator 10 as illustrated in FIGS. 6A and 6B, is not necessarily required. Consequently, for example, a process of providing the adhesive portion 60 of FIG. 6A and a process of providing the recess 10c of FIG. 6B in the first insulator 10 can be omitted.

A shape of the protrusion 10p is not limited to the shape shown in FIG. 7, but desirably, the protrusion 10p extends along the Z direction. The first insulator 10 is formed, for example, by pouring a material forming the first insulator 10 into a mold and removing the first insulator 10 from the mold. When the protrusion 10p extends along the Z direction, the mold can be removed without getting stuck when removing the mold along the Z direction. In other words, when changing the shape of the mold into which the material forming the first insulator 10 is poured, it is not necessary to increase the number of processes of forming the protrusion 10p.

### Second Modification of First Embodiment

FIG. 8 shows a perspective view of a semiconductor device 102 according to a second modification of the first embodiment. The description of the common parts in the semiconductor device 100 according to the first embodiment will not be repeated. The dashed line represents a portion hidden by the first insulator 10 or the conductive plate 50.

In the semiconductor device 102 according to the present modification, a groove 10g traversing the side surface 10w is provided on the side surface 10w of the first insulator 10. Here, for example, the groove 10g is defined for the side surface 10w positioned on the positive side in the X direction as follows. The groove 10g is a space positioned between the first insulator 10 and the YZ plane including the side surface 10w. It is desirable that the groove 10g extends along the Z direction.

The groove 10g is represented by the dashed line shown on the side surface 10w of the first insulator 10. The post 52 is provided along the groove 10g. The post 52 fits into the groove 10g. That is, at least a part of the post 52 is positioned more inner side of the semiconductor device 102 than the side surface 10w of the first insulator 10. The term “more inner side of the semiconductor device 102” refers to, for example, being closer to the semiconductor chip 40 of the semiconductor device 102.

In the semiconductor device 102 according to the present modification, the misalignment of the conductive plate 50 from the first insulator 10 is reduced by fitting the post 52 into the groove 10g. In FIG. 8, for example, the conductive plate 50 is prevented from being misaligned along the Y direction.

When the groove 10g is provided along the Z direction, by changing the shape of the mold for forming the first insulator 10, it is possible to form the first insulator 10 having the groove 10g. Consequently, it is not necessary to form the groove 10g by cutting the first insulator 10 later, and it is possible to shorten the manufacturing process.

### Third Modification of First Embodiment

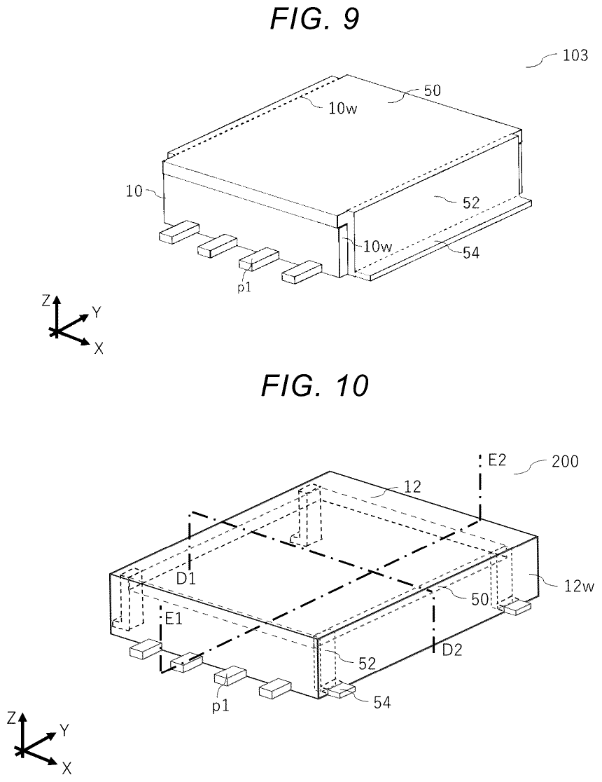

FIG. 9 shows a perspective view of a semiconductor device 103 according to a third modification of the first embodiment. The description of the common parts in the semiconductor device 100 according to the first embodiment will not be repeated.

The post 52 of the semiconductor device 103 according to the present modification is formed such that a length of the post 52 in the Y direction is greater than a length of the post 52 in the Z direction. In the post 52 illustrated in FIG. 1 or 8, the length in the Z direction is greater than the length in the Y direction, but the shape of the post 52 is not limited to this.

The base 54 has the same length in the Y direction as the post 52, as illustrated in FIG. 9. It should be noted that the base 54 may have a different length in the Y direction from the post 52.

In the semiconductor device 103 according to the present modification, the switching performance of the semiconductor device can be further improved by further reducing the temporal change of the magnetic field. The post 52 is widely provided on the side surface 10w of the first insulator 10. Therefore, the temporal change of the magnetic field can further be reduced by the current flowing through the post 52.

For example, compared to the post 52 illustrated in FIG. 1, in the present modification, the post 52, of which the length in the Y direction is longer, is provided. Therefore, the magnetic field penetrating the post 52 in the X direction is larger. In addition to the current induced in the conductive plate 50 due to the change in the magnetic field, a larger current can also be induced in the post 52.

The post 52 intersects with the conductive plate 50. The post 52 is, for example, orthogonal to the conductive plate 50. Therefore, the direction of the magnetic field generated by the current flowing into the conductive plate 50 is different from the direction of the magnetic field generated by the current flowing into the post 52.

For example, the eddy current generated in the conductive plate 50 intersecting with the Z direction is effective in reducing the induced electromotive force between the current paths along the XY plane. On the other hand, for example, the eddy current generated in the post 52 intersecting with the X direction is effective in reducing the induced electromotive force between the current paths along the YZ plane.

The shape of the path of current flowing from the first terminal p1 to the second terminal p2 may be various, and the direction of the generated magnetic field may also be various. By providing both the conductive plate 50 intersecting with the Z direction and the post 52 intersecting with the X direction, it is possible to enhance the effect of reducing the temporal change of the magnetic field for various internal structures of the semiconductor device.

In the semiconductor device 103 according to the present modification, currents such as eddy currents are likely to be induced in the post 52. Therefore, the switching performance of the semiconductor device can be improved even assuming that the current paths are in various directions.

### Second Embodiment

FIG. 10 is a perspective view illustrating a semiconductor device 200 according to a second embodiment. The description of the common parts in the semiconductor device 100 according to the first embodiment will not be repeated.

The semiconductor device 200 according to the present embodiment further has a second insulator 12 so as to cover the conductive plate 50 and the post 52. The second insulator 12 is made of, for example, resin. The base 54 protrudes from the second insulator 12 on a side surface 12w of the second insulator 12. The conductive plate 50 and the post 52, indicated by dashed lines, are covered by the second insulator 12 as shown in FIG. 10.

FIG. 11 shows a cross-sectional view taken along the XZ plane passing through the line D1-D2 illustrated in FIG. 10.

The conductive plate 50 is provided on the first insulator 10, and the second insulator 12 is provided on the conductive plate 50. The second insulator 12 is in contact with the side surface 50w of the conductive plate 50. The first insulator 10 and the second insulator 12 are continuously formed. However, among the insulators 10 and 12, the part positioned in the negative direction of the Z-axis relative to the conductive plate 50 is regarded as the first insulation portion (insulator 10). The first insulator 10 and the second insulator 12 include, for example, the same type of material.

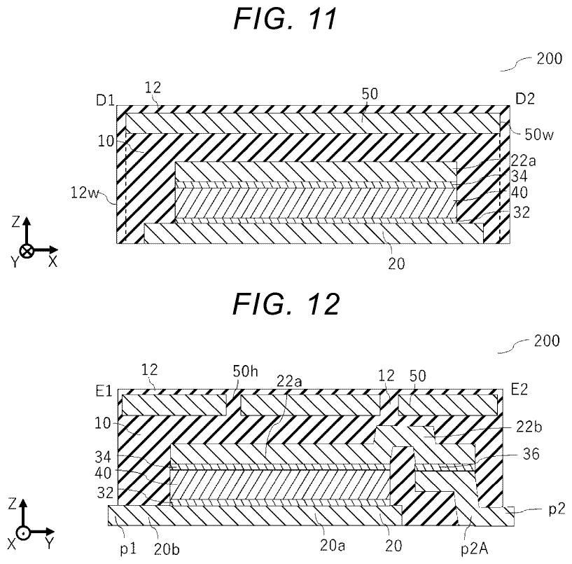

FIG. 12 shows a cross-sectional view taken along the YZ plane passing through the line E1-E2 illustrated in FIG. 10.

It is desirable that the conductive plate 50 has a hole 50h as illustrated in FIG. 12. The hole 50h is filled with the second insulator 12 and comes into contact with the first insulator 10 provided under the conductive plate 50. That is, the second insulator 12 is continuous with the first insulator 10 through the hole 50h. The hole 50h can have either a rectangular or circular shape in the XY plane. For example, the holes 50h are aligned in a dotted layout within the XY plane. Alternatively, the holes 50h can extend in the Y direction and be aligned in a striped layout within the XY plane.

In the semiconductor device 200 according to the present embodiment, the second insulator 12 that covers the conductive plate 50 and the post 52 is provided. With such a configuration, it is possible to more reliably prevent the conductive plate 50 and the post 52 from being connected to an unintended electrical potential. It is desirable that the conductive plate 50 is electrically insulated from the first terminal p1 and the second terminal p2. The upper surface and side surface of the conductive plate 50 are covered with the second insulator 12. Therefore, the conductive plate 50 and the first terminal p1 and the second terminal p2 can be electrically insulated more reliably. Further, compared to the case where the conductive plate 50 and the post 52 are exposed, when the semiconductor device 200 is mounted on the substrate or the like, the wiring of the external circuit and the conductive plate 50 and the post 52 are more reliably prevented from coming into contact with each other.

Since the conductive plate 50 has the hole 50h, when the first insulator 10 and the second insulator 12 are integrally formed, the conductive plate 50 can be in further tight contact with the first insulator 10 and the second insulator 12. The first insulator 10 and the second insulator 12, for example, include the same sealing resin, and in the sealing process, the resin flows through the hole 50h. Thereby, the second insulator 12 can be in more reliably tight contact with the conductive plate 50.

### Third Embodiment

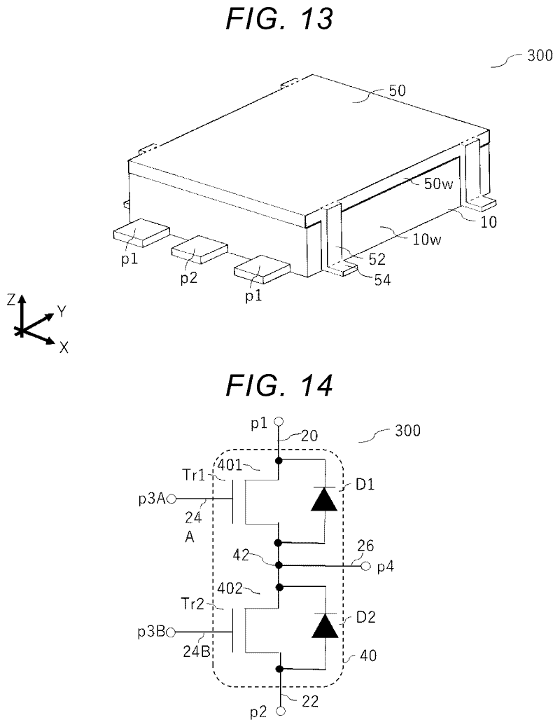

FIG. 13 is a perspective view illustrating a semiconductor device 300 according to a third embodiment.

The semiconductor device 300 has the first terminal p1 and the second terminal p2 protruding from the first insulator 10. The first terminal p1 and the second terminal p2 protrude from one side surface (a side surface positioned on the negative side in the Y direction) of the first insulator 10, as illustrated in FIG. 13. That is, the positional relationship between the first terminal p1 and the second terminal p2 is not limited to the example illustrated in FIG. 2.

The shapes of the post 52 and the like may be modified into various shapes as described in the first embodiment and its modifications. FIG. 13 illustrates the shape of the post 52 as an example only.

The semiconductor device 300 illustrated in FIG. 13 is mounted on, for example, the substrate or a cooling plate on the negative side in the Z direction. The cooling plate is, for example, a water-cooled type cooling plate.

FIG. 14 is an example of a circuit configuration of the semiconductor device 300 according to the third embodiment.

The semiconductor device 300 can be used for, for example, a part of a power conversion circuit such as an inverter circuit or a bridge circuit. The semiconductor chip 40 of the semiconductor device 300 includes a plurality of semiconductor elements (a first semiconductor element 401 and a second semiconductor element 402). A plurality of semiconductor elements are electrically connected through a wiring portion 42. The first semiconductor element 401 and the second semiconductor element 402 each have a transistor and a diode. The first semiconductor element 401 and the second semiconductor element 402 are, for example, MOSFETs.

The first terminal p1 is connected to a drain electrode of the first semiconductor element 401. The second terminal p2 is connected to a source electrode of the second semiconductor element 402. For example, a positive potential is applied to the first terminal p1, relative to the second terminal p2. Third terminals p3A and p3B are gate terminals of the first semiconductor element 401 and the second semiconductor element 402, respectively. A source electrode of the first semiconductor element 401 and a drain electrode of the second semiconductor element 402 are connected through the wiring portion 42. A potential of the connection point is the same as a potential of a fourth terminal p4. An inductive load not shown in the drawing is connected as an external load to the fourth terminal p4.

Referring to FIG. 14, the operation of the semiconductor device 300 according to the present embodiment will be described.

The semiconductor device 300 is, for example, an inverter. The first semiconductor element 401 has a transistor Tr1 and a diode D1. The diode D1 is, for example, a body diode formed through a pn junction provided in the MOSFET of the first semiconductor element 401. The second semiconductor element 402 has a transistor Tr2 and a diode D2. The diode D2 is, for example, a body diode formed through a pn junction provided in the MOSFET of the second semiconductor element 402. An external load not shown in the drawing is connected to the fourth terminal p4.

An example of the operation of switching conduction states of the transistors Tr1 and Tr2 will be described below.

First, a voltage higher than the threshold voltage is applied to the third terminal p3A. Meanwhile, a voltage lower than the threshold voltage is applied to the third terminal p3B. The transistor Tr1 of the first semiconductor element 401 is turned on. The transistor Tr2 of the second semiconductor element 402 is turned off. Thereby, for example, the on-current of the transistor Tr1 flows from the first terminal p1 to the fourth terminal p4 through the drain electrode of the transistor Tr1, the source electrode of the transistor Tr1, the wiring portion 42, and a connection region 26.

Subsequently, the voltage applied to the third terminal p3A is controlled to a voltage lower than the threshold voltage. Meanwhile, a voltage higher than the threshold voltage is applied to the third terminal p3B. The transistor Tr1 of the first semiconductor element 401 is turned off. The transistor Tr2 of the second semiconductor element 402 is turned on. Thereby, for example, the on-current of the transistor Tr2 flows from the fourth terminal p4 to the second terminal p2 through the connection region 26, the wiring portion 42, the drain electrode of the transistor Tr2, and the source electrode of the transistor Tr2.

Thereafter, when the transistor Tr2 is further switched from on to off, the current from the fourth terminal p4 to the second terminal p2 is cut off. Further, when the transistor Tr1 is continuously switched from the off state to the on state, the on-current of the transistor Tr1 flows again from the first terminal p1 to the fourth terminal p4. In such a manner, by switching the on and off of the transistors Tr1 and Tr2, it is possible to control the temporal change of the voltage applied to the external load, which is not shown in the drawing, connected to the fourth terminal p4.

As described above, by switching the voltage applied to the third terminals p3A and p3B, the DC voltage applied between the first terminal p1 and the second terminal p2 can be converted into an AC voltage which is output from the fourth terminal p4.

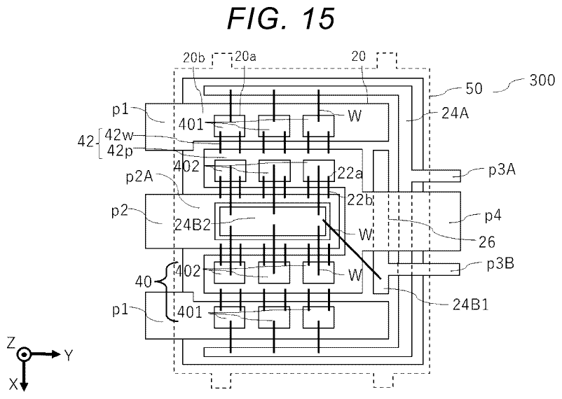

FIG. 15 is a top view of a semiconductor device 300 according to the third embodiment. It should be noted that FIG. 15 illustrates the conductive plate 50 and the insulator 10 in a transparent manner.

The semiconductor chip 40 of the semiconductor device 300 has a plurality of semiconductor elements (the first semiconductor elements 401 and the second semiconductor elements 402). The semiconductor device 300 has the wiring portion 42 that connects the semiconductor elements. Further, a plurality of (six in FIG. 15) first semiconductor elements 401 and a plurality of (six in FIG. 15) second semiconductor elements 402 may be provided. The first semiconductor element 401 and the second semiconductor element 402 each have a semiconductor substrate containing, for example, SiC. That is, the plurality of semiconductor elements (the first semiconductor elements 401 and the second semiconductor elements 402) connected through the wiring portion 42 are provided between the first terminal p1 and the second terminal p2.

A description will be given of an example in which the first semiconductor elements 401 and the second semiconductor elements 402 each have a drain electrode on the negative side in the Z direction (the side of the first conductive member 20 and the second conductive member 22) and a source electrode and a gate electrode on the positive side in the Z direction in FIG. 15.

The first terminals p1 are connected to the drain electrodes of the first semiconductor elements 401 among the semiconductor chips 40 through the first conductive member 20. The first conductive member 20 has a first region 20a facing the drain electrode of the first semiconductor element 401 and a second region 20b positioned between the first region 20a and the first terminal p1.

A gate pad is provided on the upper surface of the first semiconductor element 401, and a potential of the gate pad is controlled through the third terminal p3A. A fourth conductive region 24A is provided between the third terminal p3A and the first semiconductor element 401, and the fourth conductive region 24A and the gate pad of the first semiconductor element 401 are connected through, for example, a wire W.

The source electrode on the upper surface of the first semiconductor element 401 is connected to the drain electrode on the lower surface of the second semiconductor element 402 through the wiring portion 42. The wiring portion 42 has a wire 42w, one end of which is connected to the source electrode of the first semiconductor element 401, and a pad 42p, to which the other end of the wire 42w is connected. The second semiconductor element 402 is provided on the pad 42p. The wiring portion 42 is continuous with the fourth terminal p4. The connection region 26 positioned between the wiring portion 42 and the fourth terminal p4 is separated from the fourth conductive region 24A and a fifth conductive region 24B1 to be described later in the Z direction.

A gate pad is provided on the upper surface of the second semiconductor element 402, and a potential of the gate pad is controlled through the third terminal p3B. The fifth conductive region 24B1 is provided in series with the third terminal p3B. The fifth conductive region 24B1 and a sixth conductive region 24B2 are connected through, for example, the wire W. The sixth conductive region 24B2 is connected to the gate pad of the second semiconductor element 402 through, for example, the wire W.

The source electrodes of the second semiconductor elements 402 among the semiconductor chips 40 are connected to the second terminal p2 through the second conductive member 22. The end region p2A is continuous with the second terminal p2. The second conductive member 22 has a first region 22a connected to the source electrode of the second semiconductor element 402 and a second region 22b having one end connected to the first region 22a and the other end connected to the end region p2A.

As described above, the number of semiconductor elements provided in the semiconductor chip 40 between the first terminal p1 and the second terminal p2 is not limited to one.

FIG. 15 shows an example in which the wire 42w of the wiring portion 42 and the second region 22b of the second conductive member 22 are formed as wires. However, a metal member other than a wire may be used for the wire 42w and the second region 22b. For example, a plate-shaped metal member may be used. The configuration, in which the first semiconductor element 401 is disposed to be divided into six pieces, in FIG. 15 is merely an example, and it is desirable that at least one first semiconductor element 401 is provided. For example, when one first semiconductor element 401 having a large area in the XY plane is provided, a plate-shaped metal member may be used instead of the wire.

In the example illustrated in FIG. 15, the path, through which the current mainly flows when the semiconductor device 300 operates, includes the following two paths. One path is a path of current that flows from the first terminal p1 to the fourth terminal p4 through the first conductive member 20, the first semiconductor element 401, the wiring portion 42, and the connection region 26, or a path of current that flows in the opposite direction. The other path is a path of current that flows from the fourth terminal p4 to the second terminal p2 through the connection region 26, the wiring portion 42, the second semiconductor element 402, and the second conductive member 22, or a path of current that flows in the opposite direction.

It is desirable that the conductive plate 50 is provided at a position at which the conductive plate 50 faces at least a part of the wiring portion 42 or the second conductive member 22 in the Z direction with the first insulator 10 interposed therebetween. One end of each of the wire 42w of the wiring portion 42 and the second region 22b of the second conductive member 22 is provided on the upper surface of the first semiconductor element 401 or the second semiconductor element 402. That is, for example, the second conductive member 22 of the wiring portion 42 has a portion positioned in the positive direction of the Z-axis, relative to the first conductive member 20. Part of the second conductive member 22 of the wiring portion 42 is spaced apart from the mounting substrate in the Z direction.

It is more desirable that the conductive plate 50 faces at least a part of the wire 42w of the wiring portion 42 or the second region 22b of the second conductive member 22 in the Z direction with the first insulator 10 interposed therebetween. Further, desirably, at least a part of the conductive plate 50 faces the connection region 26 in the Z direction with the first insulator 10 interposed therebetween.

When the semiconductor device 300 according to the present embodiment is a semiconductor device having a plurality of semiconductor elements, the conductive plate 50 prevents the induced electromotive force from being generated between a plurality of current paths. Thereby, it is possible to improve the switching performance of the semiconductor device.

The conductive plate 50 is provided at a position at which the conductive plate 50 faces at least a part of the wiring portion 42 or the second conductive member 22 in the Z direction with the first insulator 10 interposed therebetween. The wire 42w of the wiring portion 42 or the second region 22b of the second conductive member 22 is a current path that is further away in the positive direction of the Z direction than the first conductive member 20, from the mounting substrate and the like, on which the semiconductor device 300 is mounted to have the lower surface being in contact therewith. The conductive plate 50 provided on the upper surface of the semiconductor device 300 is able to reduce the temporal change of the magnetic field caused by the current path at a position away from the mounting substrate and the like.

First, a description will be given of a case where the conductive plate 50 overlaps with the second conductive member 22. The temporal change of the magnetic field caused by the current flowing through the second conductive member 22 can be reduced by the current induced in the conductive plate 50 positioned on the positive side in the Z direction relative to the second conductive member 22.

Referring to FIG. 14, for example, when the third terminal p3A is turned off, the temporal change of the current, which flows through the diode D2 of the second semiconductor element 402 from the second terminal p2 to the fourth terminal p4, may occur. Alternatively, when the third terminal p3B is turned on, the temporal change of the current, which flows through the transistor Tr2 of the second semiconductor element 402 from the fourth terminal p4 to the second terminal p2, may occur. In such a manner, when the third terminal p3A or p3B is switched, the temporal change of the current, which passes through the second conductive member 22 connected to the second semiconductor element 402, may occur. With the conductive plate 50 positioned on the positive side in the Z direction relative to the second conductive member 22, it is possible to reduce the temporal change of the magnetic field at the time of switching. As a result, it is possible to reduce voltage oscillation.

On the other hand, the conductive plate 50 may overlap with the wiring portion 42 in the Z direction. In such a case, the temporal change of the magnetic field generated by the current flowing through the wiring portion 42 can be reduced by the current induced in the conductive plate 50 positioned on the positive side in the Z direction relative to the wiring portion 42. Consequently, it is possible to reduce the voltage oscillation at the time of switching the third terminals p3A and p3B of the semiconductor device 300.

The conductive plate 50 also serves as a path for heat flow. Therefore, in the semiconductor device 300, for example, the heat generation portion may be uneven in the XY plane due to the arrangement of the plurality of semiconductor chips 40. In such a case, the heat is conducted to the conductive plate 50 with the first insulator 10 interposed therebetween, and the heat is diffused in the conductive plate 50. Thereby, the amount of heat generation can be more uniform within the XY plane. By preventing local heat from being generated, it is possible to improve the reliability of the semiconductor device 300.

The conductive plate 50 is electrically and thermally connected to the external circuits through the base 54 and the post 52 connected to the conductive plate 50. It is possible to lay out wiring that connects the external circuits through the conductive plate 50. Further, by dissipating heat to the external circuits, heat is prevented from accumulating in the conductive plate 50.

In the semiconductor device according to at least one embodiment among the first to third embodiments described above, when the semiconductor chip 40 has at least one semiconductor element, the conductive plate 50 reduces the effect of the magnetic field caused by the current flowing through the semiconductor device. Thereby, it is possible to improve the switching performance of the semiconductor device. When the conductive plate 50 at least partially overlaps with the second conductive member 22 connecting the second terminal p2 to the semiconductor chip 40 in the Z direction, the switching performance can be further improved, which is desirable. Further, the conductive plate 50 also serves as a path for heat flow. Therefore, by preventing the semiconductor device from overheating locally, it is possible to improve reliability.

The embodiments were hitherto described above with reference to specific examples. However, the embodiments are not limited to such specific examples. In other words, even when a person who is skilled in the art applies an appropriate design change to these specific examples, those are included in the scope of the embodiments as long as they have the features of the embodiments. The elements and their arrangements, materials, conditions, shapes, sizes, and the like of each specific embodiment described above are not limited to those exemplified and can be appropriately changed.

Each element of each embodiment described above can be combined as much as technically possible, and combinations of these elements are also within the scope of the embodiment as long as the elements include the features of the embodiment. In addition, those skilled in the art is able to conceive of various other changes and modifications within the scope of the concept of the embodiments, and such changes and modifications are understood to be within the scope of the embodiments.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first terminal and a second terminal;
a first conductive member that is electrically connected to the first terminal;
a semiconductor chip that is provided on the first conductive member;
a second conductive member that is provided on the semiconductor chip and electrically connected to the second terminal;
a first insulator that is provided on the second conductive member and covers the semiconductor chip;
a conductive plate that is provided on at least a part of the first insulator; and
a post that is electrically connected to the conductive plate and extends along a side surface of the first insulator.

2. The semiconductor device according to claim 1, wherein the second conductive member includes:
a first region facing the semiconductor chip in a first direction that extends from the first conductive member to the semiconductor chip; and
a second region positioned between the first region and the second terminal.

3. The semiconductor device according to claim 2, further comprising:
a base that is continuous with the post and extends within a first plane intersecting the first direction.

4. The semiconductor device according to claim 2, wherein the conductive plate is longer than the second conductive member in a second direction that extends from the first terminal to the first conductive member and intersects the first direction.

5. The semiconductor device according to claim 2, wherein the conductive plate is longer than the second conductive member in a third direction intersecting the first direction and a second direction that extends from the first terminal to the first conductive member and intersects the first direction.

6. The semiconductor device according to claim 1, wherein
an adhesive portion is provided on at least a part of a space between the first insulator and the conductive plate, and
the first insulator includes an epoxy resin, and the adhesive portion includes a silicone-based adhesive.

7. The semiconductor device according to claim 2, wherein
a protrusion protruding in the first direction is provided on an upper surface of the first insulator, and
a recess is provided on a lower surface of the conductive plate at a position corresponding to the protrusion.

8. The semiconductor device according to claim 2, wherein
a groove extending in the first direction is provided on the side surface of the first insulator, and
at least a part of the post is provided in the groove.

9. The semiconductor device according to claim 1, further comprising a second insulator that is provided on the conductive plate.

10. The semiconductor device according to claim 1, further comprising:
a bonding member that is provided between the semiconductor chip and the second conductive member,
wherein the second conductive member is a plate-shaped metal member.

11. The semiconductor device according to claim 1, wherein
the semiconductor chip includes
a first semiconductor element that is provided on the first conductive member, and
a second semiconductor element that is electrically connected to the first semiconductor element through a wiring portion and electrically connected to the second conductive member, and
the second conductive member faces the second semiconductor element in a first direction that extends from the first conductive member to the first semiconductor element.

12. The semiconductor device according to claim 11, wherein the first semiconductor element and the second semiconductor element each include a MOSFET, and the semiconductor device further includes:
a plurality of third terminals respectively connected electrically to a gate electrode of the MOSFET of the first semiconductor element and a gate electrode of the MOSFET of the second semiconductor element, and
a fourth terminal electrically connected to the wiring portion.

13. The semiconductor device according to claim 12, wherein the semiconductor chip further includes:
one or more other first semiconductor elements in addition to the first semiconductor element and one or more other second semiconductor elements in addition to the second semiconductor element.

14. A semiconductor device comprising:
a first conductive member;
a semiconductor chip that is provided on the first conductive member;
a second conductive member that is provided on the semiconductor chip;
a first insulator that is provided on the second conductive member and covers the semiconductor chip;
a conductive plate that is provided on the first insulator and has at least a part facing the second conductive member in a first direction; and
a conductive base that can be used as a terminal for external connections; and
a conductive layer that electrically connects the conductive plate and the conductive base.

15. The semiconductor device according to claim 14, wherein the conductive layer is a post that extends in the first direction along a side surface of the first insulator.

16. The semiconductor device according to claim 14, wherein the conductive base is provided on a first side surface of the first insulator and on a second side surface of the first insulator that is on an opposite side of the first insulator with respect to the first side surface.

17. A semiconductor device comprising:
a first terminal and a second terminal;
a first conductive member that is electrically connected to the first terminal;
a semiconductor chip that is provided on the first conductive member;
a second conductive member that is provided on the semiconductor chip and electrically connected to the second terminal;
a first insulator that is provided on the second conductive member and covers the semiconductor chip; and
a conductive plate that is provided on at least a part of the first insulator,
wherein the first insulator is directly interfaced with the second conductive member and the conductive plate.

18. The semiconductor device according to claim 17, wherein the first insulator extends continuously from the first terminal to the second terminal and between the second conductive member and the conductive plate.
